(19) United States
(12) Patent Application Publication
(10) Pub. No.: US 2025/0308605 A1
(43) Pub. Date: Oct. 2, 2025

(54) PROGRAM ERROR HANDLING AT A STORAGE DEVICE

(71) Applicant: Microchip Technology Incorporated, Chandler, AZ (US)

(72) Inventors: Pitamber SHUKLA, San Jose, CA (US); Saswati DAS, Milpitas, CA (US); Nian Niles YANG, Mountain View, CA (US); Srinivas YELISETTI, Fremont, CA (US)

(21) Appl. No.: 18/984,995

(22) Filed: Dec. 17, 2024

Related U.S. Application Data
(60) Provisional application No. 63/570,803, filed on Mar. 27, 2024.

(51) Int. Cl. G11C 16/34; G11C 16/10; G11C 29/52

(52) U.S. Cl. CPC G11C 16/3459; G11C 16/102; G11C 29/52

(57) ABSTRACT

In some implementations, a storage device may receive, from a host device, a write command. The storage device may perform a first write operation to write data on a first word line of a block of a virtual block associated with multiple blocks. The storage device may identify a program error associated with the write operation on the first word line. The storage device may perform a second write operation to write additional data on a second word line of the block. In some aspects, the storage device may perform the second write operation after checking and confirming on the reliability of the block through dummy data write operation on subsequent word lines.

### CROSS-REFERENCE TO RELATED APPLICATION

This Patent Application claims priority to U.S. Patent Application No. 63/570,803, filed on 27 Mar. 2024, and entitled “PROGRAM ERROR HANDLING AT A STORAGE DEVICE.” The disclosure of the prior Application is considered part of and is incorporated by reference into this Patent Application.

### FIELD

The present disclosure generally relates to write operations performed on a storage device. The storage device may attempt to write data to one or more word lines or one or more multi-block word lines (e.g., a virtual word line on a virtual block). As part of a write operation, or in connection with the write operation, the storage device may detect a program error at a word line. The present disclosure generally relates to operations performed in response to detection of a program error during the write operation.

### SUMMARY

In some implementations, a method performed by a storage device includes receiving, from a host device, a write command. The method includes performing a first write operation to write a first set of data on a first word line of a block in a plurality of blocks included in a virtual block. The method includes identifying a program error associated with the write operation on the first word line. The method includes performing a second write operation to write a second set of data on a second word line of the block.

In some implementations, a system comprises a controller, of a non-volatile memory device, to initiate a first write operation to write a first set of data on a first word line of a block in a plurality of blocks included in a virtual block. The controller is further to identify a program error associated with the write operation at the first word line. The controller is further to perform a dummy data write operation on a second word line of the block. The controller is further to perform a second write operation to write a second set of data on a third word line of the block based at least in part on the dummy data write operation having no program error.

In some implementations, a computer program product comprises one or more computer readable storage media and program instructions collectively stored on the one or more computer readable storage media. The program instructions comprise program instructions to receive, from a host device, a write command. The program instructions further comprise program instructions to initiate a write operation to write a first set of data on a first word line of a block in a plurality of blocks included in a virtual block. The program instructions further comprise program instructions to identify a program error associated with the write operation at the word line. The program instructions further comprise program instructions to perform a second write operation to write a second set of data on a second word line of the block, the second word line separated from the first word line by one or more word lines based at least in part on identification of the program error.

### BACKGROUND

A non-volatile memory device may include a storage device (e.g., a memory device) that may store and retain data without external power supply. One example of a non-volatile memory device is a NOT-AND (NAND) flash memory device.

The storage device may store data at various physical locations of the storage device. For example, the storage device may support storage of data at locations of the storage device. Locations of the storage device may be referred to using physical and logical addresses.

A virtual block (VB) is a collection of blocks across multiple logical unit numbers (LUNs). A VB has a size that varies according to number of bad blocks. For example, if no bad blocks, the size=(# Channels)×(# Targets)×(# LUNs)×(Physical Block Size). The VB includes multiple virtual pages. A virtual page is a collection of pages across multiple LUNs in a VB. A virtual page is a redundant array of independent disks (RAID) stripe which contains one or two XOR parity pages. The number of virtual pages in a VB is equal to the number of pages of a single block. Similarly, a virtual word line is a collection of word lines across all LUNs in a VB. A flash transition layer (FTL) may handle blocks in a VB unit. The FTL manages a list of VBs according to states (e.g., free, open, used).

When performing a write operation, the storage device may detect a program error that is associated with a physical error of the storage device at one or more elements, such as a word line. There are many possible physical defects such as word line to word line shorts, word line to channel shorts, or word line to source shorts, among other examples. A word line to word line short defect can be caused by one or more particles that bridge two or more word lines. During a program operation, a word line to word line short may cause drop in program voltage at a targeted word line, which in turn may result in a program status fail of a subsequent word line and program disturb on a previous word line associated with a limit of program loops on the targeted word line.

In some examples, if there is a program error, the storage device (e.g. a controller) may mark a dual plane physical block (e.g., for a 2 plane of the storage device) and quad plane physical block (e.g., for a 4-plane of the storage device) as bad blocks and issue garbage collection to the entire virtual block. During garbage collection, the storage device may transfer data from the current virtual block to a new virtual block and free up the current virtual block, which is eventually erased and used for programming new data. Future storage devices may have even higher number of planes, such as 8 planes, where performing garbage collection to the entire virtual block would cause significant overhead in moving data and erasing data.

### BRIEF DESCRIPTION OF THE DRAWINGS

FIGS. 1-3 are diagrams of examples of program error handling at a storage device described herein.

FIGS. 4 and 5 are diagrams of example components of one or more devices of FIGS. 1-3.

FIGS. 6-8 are flowcharts of example processes associated with program error handling at a storage device described herein.

### DETAILED DESCRIPTION

The following detailed description of example implementations refers to the accompanying drawings. The same reference numbers in different drawings may identify the same or similar elements.

When performing a write operation, a storage device (e.g., a NOT-AND (NAND) device or a non-volatile memory device, among other examples) may detect a program error that is associated with a physical error of the storage device at one or more elements, such as a word line. In some examples, the storage device may mark an entire virtual block associated with the word line for garbage collection. Marking the entire virtual block (e.g., a dual plane physical block for a 2 plane storage device or quad plane physical block for a 4-plane storage device, among other examples) as bad blocks during a program error significantly reduces the effective over provisioning (OP) of the storage device. As OP decreases, write amplification increases. Also, doing urgent garbage collection to the entire virtual block (VB) significantly increases write amplification due to transferring of valid data to the new block without considering valid data count.

Write amplification also increases PE cycles of the blocks, thereby reducing life-time of the storage device. Write amplification may also decrease write throughput and increase write latencies, as well as significantly increasing read latency in a mixed workload.

After transferring the data to the new block, the VB is freed and eventually erased to program new data. Over time, multiple open block erase operations will reduce the reliability of the NAND blocks. In some examples, open block erase operations may cause a deep erase on unprogrammed word lines and shallow erase on programmed word lines. This may cause further errors in subsequent write operations.

In some aspects described herein, a storage device may adaptively program remaining possible word lines in a physical block that encountered a program status fail by continuing to write data on other word lines of non-erroneous physical blocks in the VB. The storage device may check the program status on subsequent word lines of the erroneous physical block using a dummy data write during a subsequent programming sequence. For example, the storage device may write the dummy data on subsequent word lines and check for program errors in the subsequent word lines.

In some aspects, a firmware solution may be used to perform the dummy data write and program status check on a few (e.g., configured or predetermined) number of subsequent word lines in the block associated with the program error in a subsequent data programming sequence. In this way, the storage device may identify the potential good physical locations for the write operation.

In some aspects, the storage device may scan previously written data on prior word lines of the block to check data integrity and reliability of the physical block and determine whether to move valid data of the virtual block to a new virtual block through urgent garbage collection.

Based at least in part on writing data to the VB having the program error and using a scan read to avoid redundant garbage collection, the storage device may reduce over-provisioning (OP) associated with program errors. Similarly, the storage device may reduce write amplification incurred by reducing urgent garbage collect to reduce the impact of a program error. Also, the storage device may improve reliability by avoiding open block erase.

In some aspects, when a program error happens, instead of marking an entire multiplane physical block (e.g., a VB) as bad blocks, the storage device may perform error mitigation operation to conserve effective OP. In some aspects, the storage device may mark current data frames (e.g., a set of data) belonging to a word line associated with the program error as invalid and may reprogram the user data of the current erroneous word line to a different good physical block during the next programming sequence.

Instead of closing (or discarding) the VB, the storage device may keep the VB active and continue writing to the VB. In the next programming sequence to the VB, the storage device may write user data to the good physical blocks and dummy data on the next word line in the erroneous physical block to determine a reliability of the subsequent word line of the erroneous physical block. RAID parities for the subsequent word line will also be calculated based on the user data on the good physical blocks and dummy data in the erroneous physical block. If a dummy data write to the subsequent word line does not encounter a program error, then the physical block is considered good, and the storage device may continue writing user data to the subsequent word lines of the physical block.

If the dummy data write to the subsequent word line in the physical block encounters a program error, the storage device may continue dummy data writes to the next X number of word lines in the physical block. The storage device may identify a word line that does not encounter a program error in the next X number of word lines in the physical block, or the storage device reaches a last word line of the VB. If the storage device identifies a good word line (e.g., without a program error) within the X number of word lines, the storage device may use remaining word lines to write user data to the erroneous physical block. The value of X may depend on PE cycles of the VB or can be a specified number.

If dummy data writes to X consecutive word lines and each produces a program error, the VB may be marked as bad blocks (e.g., the entire VB or one or more blocks of the VB associated with the program error), and the size of the current active virtual block may be reduced for subsequent write operations.

In some examples, if a program error is faced in a physical block, previously programed data on a few of the prior word lines of the physical block will be checked with a scan read (e.g., where the controller performs multiple reads across a range of voltage thresholds to identify information about a state of a memory cell) to determine reliability. This may help to identify effects of a word line to word line short that may cause the program operation to disturb previously programed word lines.

Scan reads may be issued on lower page, middle page, or upper page locations (e.g., in case of TLC or all 4 pages for QLC) of the previous word lines of the erroneous block (e.g., one by one). A scan frequency or scan location may be device specific (e.g., NAND specific) or based at least in part on a failure mode signature (e.g., NAND failure mode signature). For example, the word line prior to the program error word line may be scanned more frequently than other word lines, as it is most likely to be impacted from a word line to word line short.

If the previous Y word lines are identified as good (e.g., without program errors) via scan reads, the storage device may not issue urgent garbage collection operations on the corresponding virtual block based on the program error. The value of Y may be determined based at least in part on PE cycles or a number of read retries performed on the VB. If the scan read for any of the prior written word lines produces an error, the VB may be marked as bad blocks, and the VB may be added to a reclaim list. The storage device may then issue an urgent garbage collection operation to move the valid data to a new virtual block. In some aspects, the storage device may keep a count of the number of read retries issued per VB to be used in determining the value of Y.

A scan read (e.g., of the previous Y word lines) may be issued to avoid an urgent garbage collection operation on the virtual block if the number of program errors is limited to 1 physical word line per virtual word line, so that RAID parity may recover the error in the worst case.

Overall, by issuing adaptive scan reads, the storage device may avoid unnecessary garbage collection and thus reduce write amplification and avoid re-erasing of erased word lines due to garbage collection of partially written virtual blocks.

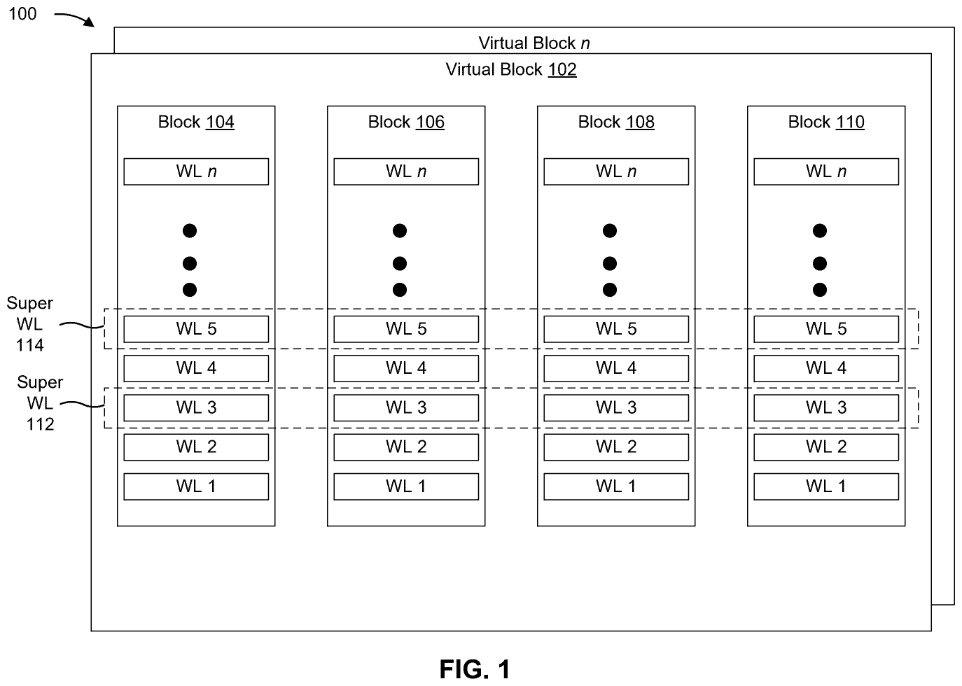

FIG. 1 is a diagram of an example 100 of program error handling at a storage device described herein. The operations described in connection with example 100 may be performed by a storage device, or one or more components of the storage device, such as a controller (e.g., a NAND controller), among other examples. Although examples may be described in connection with FIG. 1 as an SSD or NAND device, other storage devices are intended to be interchangeable in the context of the described aspects and examples.

As shown in FIG. 1, a storage device may include one or more virtual blocks 102 that includes one or more physical components for storing data. For example, the virtual block 102 may include transistors organized into physical and logical units for storing data. The virtual block 102 may include a set of blocks 104, 106, 108, and 110. In some aspects, the virtual block 102 may include any number of blocks. As shown in FIG. 1, the virtual word line 102 that includes blocks 104, 106, 108, and 110 may be a combination of word lines of multiple physical blocks from different planes of a die out of different dies.

In some aspects described herein, the storage device may perform a program operation at the virtual block 102. For example, the storage device may write data to word line 3 of block 104. After, or as part of, the program operation, the storage device may detect a program error. For example, the program error may be associated with a physical defect of a physical component of the block 104 (e.g., a bit line).

Based at least in part on detecting the program error on the word line 3 of block 104, the storage device may attempt to write the data that encountered the error at the next-in-order word line (e.g., at another block). In some aspects, the storage device may attempt to write the data originally intended for word line 3 of block 104 to the word line of another block (e.g., word line 3 of block 106, 108, or 110 or word line 4 of block 106, 108, or 110). In other examples, storage device may skip one or more word lines of the block 104 and attempt to write the data to, for example, word line 5 of block 104, 106, 108, or 110. In some aspects, the storage device may write dummy data on the one or more skipped word lines of block 104 before attempting to write the data to another word line. For example, the storage device may write dummy data to word line 4 and, based at least in part on not detecting a program error in the dummy data at word line 4, the storage device may write the data to word line 5.

If the second attempt to write the data (e.g., on a second word line) on block 104 is successful (e.g., without a program error), or if writing the dummy data on the one or more skipped word lines is successful (e.g., without a program error), then the storage device may continue using block 104 as an open block that supports further write operations. If the second attempt to write the data (e.g., the same data or other data) on block 104 fails (e.g., another program error is detected), or if writing the dummy data on the one or more skipped word lines fails (e.g., a program error is detected), the storage device may mark the block 104 as a bad block, may mark the virtual block 102 as bad blocks, or may perform a third attempt to write data on block 104 (e.g., at a third word line of the block 104) or may attempt again to write dummy data on additional word lines of the block 104. In some aspects, the storage device may mark the block 104, or the entire virtual block 102, as bad and may schedule the virtual block for garbage collection after a threshold for a number of failed attempts to write data or dummy data on block 104 is satisfied.

In some aspects, the storage device may scan one or more previous word lines for a read error based at least in part on detecting the program error on word line 3 of block 104. For example, the storage device may scan word line 2 to identify a scan read error or a voltage leak that may be associated with another error on word line 2. In some aspects, the storage device may scan multiple word lines for a scan read error until a word line is found without a scan read error. In this way, the storage device may identify a range of word lines with scan read errors.

In some aspects, based at least in part on identifying the program error on word line 3 of block 104, the storage device may write dummy data to one or more word lines of block 104. In some aspects, the storage device may write dummy data on one or more skipped word lines (e.g., word line 4 of block 104 and then on word line 5 of block 104 if word line 4 faces encounters a program error). In some aspects, the storage device may write dummy data on one or more skipped word lines on one or more of the remaining blocks 106, 108, or 110.

In some aspects, the storage device may identify a quantity of word lines having program errors on block 104. If the quantity satisfies a threshold, the storage device may mark block 104 as a bad block and schedule garbage collection on the virtual block 102. The virtual block may be reconfigured with a reduced size after skipping the bad block after the garbage collection operation:

The number and arrangement of components shown in FIG. 1 are provided as an example.

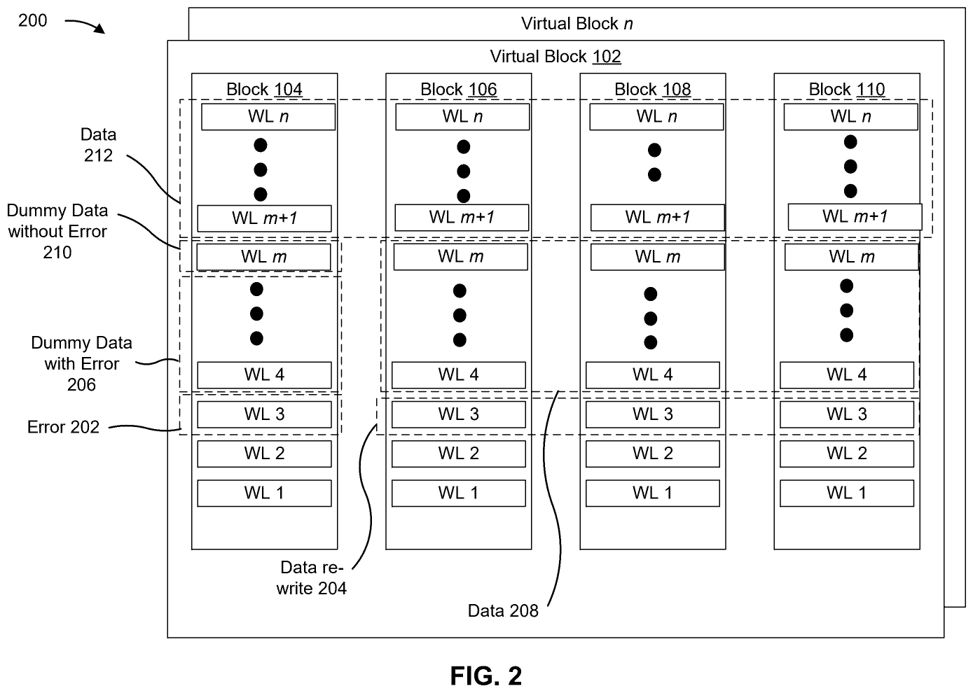

FIG. 2 is a diagram of an example 200 of program error handling at a storage device described herein. FIG. 2 shows the one or more virtual blocks, including the virtual block 102 that includes the set of blocks 104, 106, 108, and 110. In the example 200, the storage device may detect a program error and, instead of marking the entire block 104 (e.g., a set of multiplane physical blocks) as a bad block, the storage device may perform mitigation operations to conserve OP.

As shown in FIG. 2, the storage device may write data on word lines of the blocks 104, 106, 108, and 110 of the virtual block 102. In some aspects, the storage device may identify a program error 202 at word line 3 of block 104. The storage device may mark current data frames associated with the word line in the block 104 as invalid and may reprogram the data of the erroneous word line to a different, good physical block during a subsequent programming sequence. For example, the storage device may write the data associated with word line 3 of block 104 on a word line of another block 106, 108, or 110, as shown by data rewrite 204. In some aspects, the storage device may perform the data re-write 204 on a same word line as the error 202 or on a different word line (e.g., at word line 4). In this way, the storage device may keep the virtual block 102 active and continue to write to the virtual block 102, rather than closing the virtual block 102, as may otherwise happen in other systems.

In a subsequent programming sequence to the virtual block 102, the storage device may write dummy data 206 to the block 104 based at least in part on having the error 202. In some aspects, the storage device may write data 208 (e.g., data that is different from data 104) to good physical blocks (e.g., blocks 106, 108, and 110 without program errors) on a subsequent word line. In this way, the storage device may use a word line at other blocks of virtual block 102 even though there is an error at block 104 or even though there is dummy data written to block 104 at the same word line as the other blocks. The storage device may use the dummy data to determine reliability of a subsequent word line of the block 104.

In some aspects, the storage device may use RAID parities for the word lines having the dummy data that use, for parity, the data 208 on the good blocks 106, 108, and 110, and the dummy data 206 in the current erroneous block 104.

As shown in FIG. 2, the dummy data is indicated as dummy data with error 206. For example, the storage device may detect a program error on the dummy data stored at word line 4 of block 104. Based at least in part on detecting the dummy data with error 206, the storage device may continue writing dummy data on subsequent word lines of the block 104 until finding a word line of the block 104 that has no program error after writing the dummy data or until reaching the final word line of the block 104. The storage device may continue writing data 208 on blocks 106, 108, 110 in the word lines corresponding to the dummy data writes on block 104.

The storage device may write dummy data on subsequent word lines of block 104 until identifying a word line that does not have an error in the dummy data (dummy data without error 210). As shown in FIG. 2, the storage device may continue to write data 208 in the corresponding word lines of blocks 106, 108, and 110. As shown in FIG. 2, the storage device may identify the dummy data without error 210 at word line m of the block 104. Based at least in part on identifying no program error at word line m of block 104, the storage device may write data 212 (e.g., a data frame or data of a subsequent write operation that is different from data 208) to the subsequent word line (e.g., word line m+1) of block 104 instead of dummy data. As shown in FIG. 2, the storage device may write the data 212, including one or more data frames or associated with one or more write operations, to the word lines m+1 to n at block 104 and one or more of blocks 106, 108, or 110.

In some aspects, the storage device may attempt a predetermined number of dummy data writes on the block 104. The predetermined number may be based at least in part on program-erase (PE) cycles of the virtual block 102 or a specific number associated with a storage medium having block 104 thereon. If the number of dummy data writes with errors (e.g., from word line 4 to word line m−1) satisfies the predetermined number, the storage device may mark the virtual block 102 as having bad blocks (e.g., the multi plane block containing block 104). In this way, a size of the virtual block 102 may be reduced for subsequent writes.

Based at least in part on writing dummy data on word lines of a block having a program error at a word line, the storage device may conserve OP of the storage device by continuing to write on other blocks of the virtual block 102. Additionally, or alternatively, the storage device may conserve OP of the virtual block 102 by detecting a word line where the program errors at block 104 are not present, allowing the virtual block 102 to have data written to block 104 at subsequent word lines (e.g., word line n and subsequent word lines).

The number and arrangement of components shown in FIG. 2 are provided as an example.

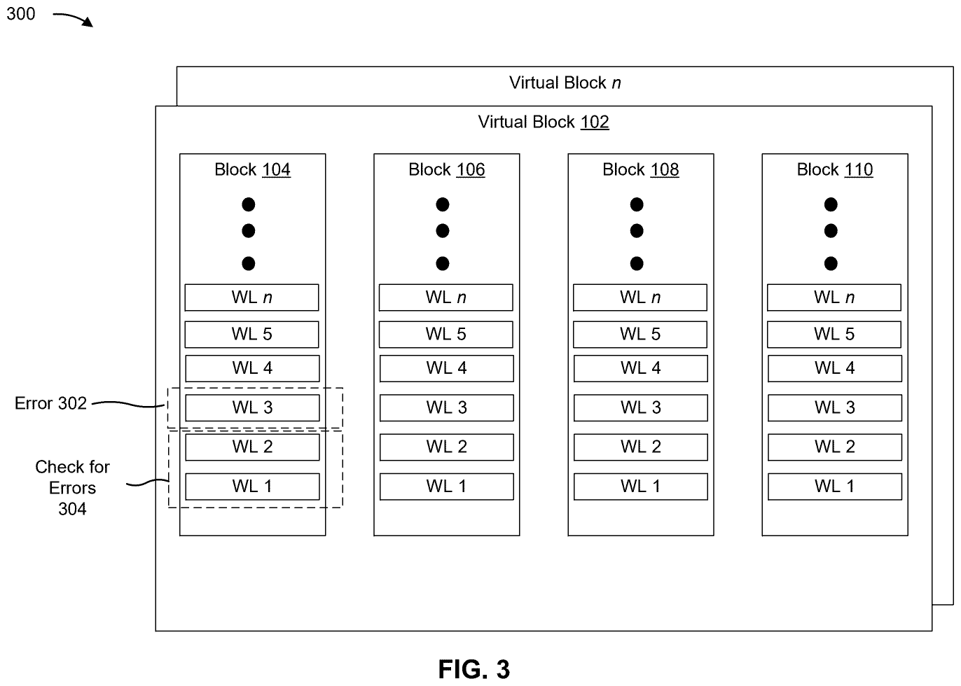

FIG. 3 is a diagram of an example 300 of program error handling at a storage device described herein. FIG. 3 shows the one or more virtual blocks, including the virtual block 102 that includes the set of blocks 104, 106, 108, and 110. In the example 300, the storage device may detect a program error and, instead of marking the multiplane physical block containing block 104 as bad blocks, the storage device may perform mitigation operations to conserve OP.

The storage device may write data on word lines of the blocks 104, 106, 108, and 110 of the virtual block 102. In some aspects, the storage device may identify a program error 302 at word line 3 of block 104. The storage device may mark current data frames associated with the word line in the block 104 as invalid and may reprogram the data of the erroneous word line to a different, good physical block during a subsequent programming sequence. For example, the storage device may write the data associated with word line 3 of block 104 on a word line of another block 106, 108, or 110, as illustrated by data rewrite 204 in FIG. 2.

Instead of closing the virtual block 102 and marking the virtual block 102 for garbage collection, the storage device may check for errors on the virtual block 102 to determine if other parts of the block 104 and/or the virtual block 102 may continue to be used for data storage.

One part of the virtual block 102 that may be susceptible to a program error may be previous word lines of the block 104 because, for example, word line to word line shorts may cause a program disturbance on previously programed word lines. For at least this reason, if a program error is faced in a physical block, the storage device may check previously programed data on a few prior word lines of the physical block using a scan read to determine reliability. For example, the storage device may check for errors 304 (e.g., using a scan read) on word line 1 and 2 (previous word lines relative to word line 3).

In some aspects, the storage device may issue scan reads on lower pages, middle pages or upper pages in case of triple-level cells (TLCs) (for quad-level cells (QLC), all the 4 pages may be checked using the scan read) of the previous word lines of the block 104. For example, the storage device may check each word line one-by-one.

A frequency or location of the scans may be specific to the storage medium associated with the block 104 or may based at least in part on a failure mode signature. For example, the word line prior to the error 302 may be scanned more frequently than other word lines, as it may be most likely to be impacted by a word line to word line short.

If the previous number ‘Y’ of word lines are found to be free from error via scan reads (e.g., no read error is identified via scan reads), the storage device may not issue an urgent garbage collection operation on the virtual block 102 based at least in part on the program error 302. The value of Y may be determined based at least in part on PE cycles or a number of read retries performed on the virtual block 102.

If a scan read performed on a previous word line produces an error, the virtual block 102 may be marked as having bad blocks, the virtual block 102 may be added to a reclaim list, and the storage device may issue an urgent garbage collection operation to move any valid data to a different virtual block. In some aspects, the storage device may use a number of read retries that is issued on a per virtual block basis to determine a value of Y.

In some aspects, the storage device may issue the scan read of the previous word lines to avoid an urgent garbage collection operation on the virtual block 102 if the number of program errors is limited to a threshold number of (e.g., 1) physical word line (e.g., at a single block) per virtual word line (on multiple blocks of the virtual block 102), so that RAID parity can recover the error.

Based at least in part on issuing adaptive scan reads to the previous word lines, the storage device may avoid unnecessary garbage collection and thus reduce write amplification and avoid re-erasing of erased word lines due to garbage collection of partially written virtual blocks.

The number and arrangement of components shown in FIG. 3 are provided as an example.

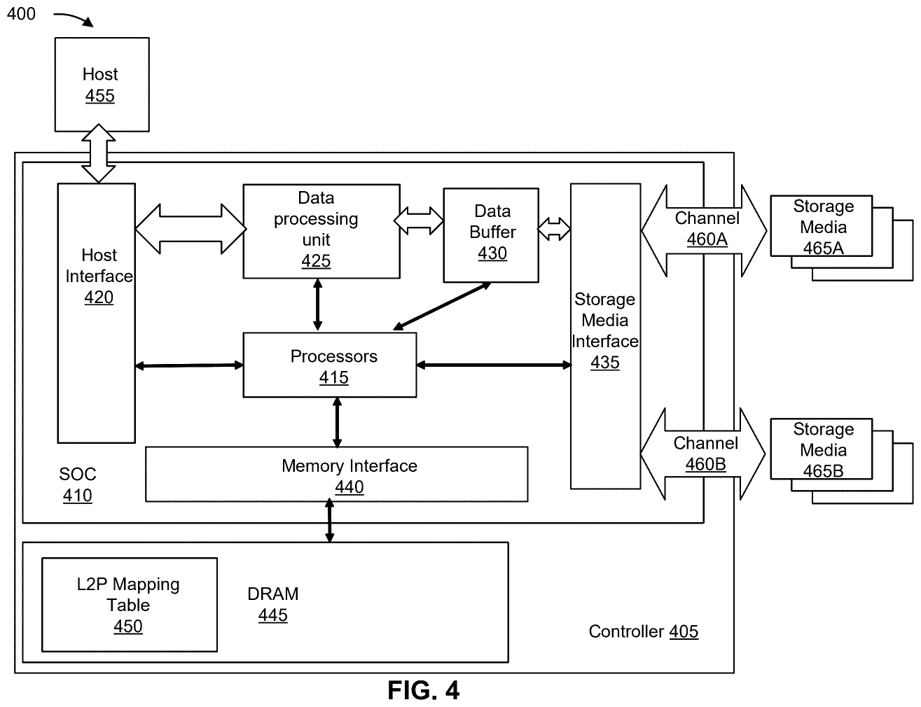

FIG. 4 is a diagram of example components of a storage device 400, which may correspond to one or more devices of FIG. 1, FIG. 2 or FIG. 3.

As shown in FIG. 4, the storage device 400 may include a controller 405 (e.g., an SSD controller). The controller 405 may include a system on chip (SOC) 410. The SOC 410 may perform computing or processing operations for the controller 405.

The SOC 410 may include one or more processors 415 that control, command, or observe operations at one or more other components of the SOC 410. The one or more processors 415 may be communicably coupled too one or more of a host interface 420, a data processing unit 425, a data buffer 430 a storage medium interface 435, or a memory interface 440.

The host interface 410 may be configured to communicate with a host device (e.g., host device 455 described below). The DPU 425 may manage data flow between the host interface 410 and storage media. The DPU 425 may further include a functional block that is responsible for managing data operations, such as reading, writing, error correction, or formatting. The DPU 425 may perform tasks such as page and block management (e.g., organization of data within storage media), bad block management, garbage collection, error correction and detection (e.g., using error correction codes or soft bit processing), data transformation (e.g., address mapping from host addresses to physical addresses, compression and decompression, or scrambling, among other examples), encryption and decryption, or power management associated with data operations, among other examples.

The data buffer 430 is a pipeline data buffer for the data transition. The data buffer 430 may include a temporary storage area used to transfer or process data between the storage media and a host system. The memory interface 440 is an interface between controller 410 and external DDR or DRAM, which may be used to temporarily hold the data. The memory interface 440 may provide an interface between the SOC 410 and the DRAM 445 to facilitate transfers of information. For example, the memory interface 440 may support requests to access a logical to physical (L2P) mapping table to identify a physical location of data requested by the host device, or to provide mapping information for storage in the L2P mapping table.

The controller 405 may further include DRAM 445. The DRAM 445 may locally store information that is available on demand at the controller 405 for operations of the controller 405. For example, the DRAM 445 may store an L2P mapping table 450 that maps logical locations of data and physical locations of data on connected storage media. In this way, the controller 405 may have access to mapping information for locating data on the connected storage media based at least in part on an indication associated with host data when written.

The host interface 420 may provide an interface for communicating with a host 455. For example, the host interface 420 may receive an access request or data for storage on connected storage media. In some aspects, the host interface 420 may provide data to the host after reading the data on from the connected storage media.

The storage media interface 435 may communicate via one or more channels 460 (e.g., 460A and 460B) with one or more connected storage media 465 (e.g., 465A and 465B). For example, the controller 405 may perform or initiate a read or write operation at a physical location of a storage media device 465.

Device 400 may perform one or more processes described herein. For example, a non-transitory computer-readable medium (e.g., memory 445 or storage component 465) may store a set of instructions (e.g., one or more instructions, code, software code, or program code) for execution by processor 415. Processor 415 may execute the set of instructions to perform one or more processes described herein. In some implementations, execution of the set of instructions, by one or more processors 415, causes the one or more processors 415 or the device 400 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 4 are provided as an example.

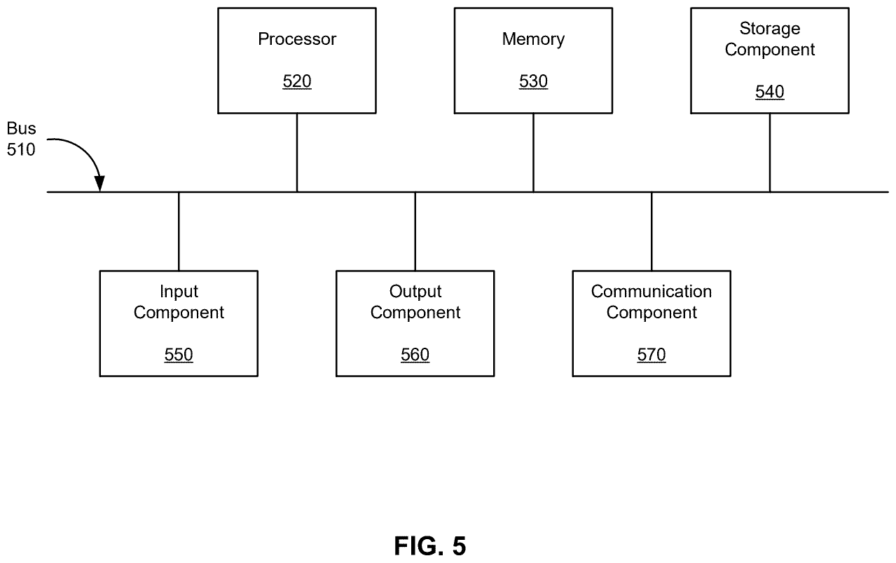

FIG. 5 is a diagram of example components of a device 500, which may correspond to one or more devices of FIG. 1-4, such as a controller 405 or a host device 455. In some implementations, the controller or the host device may include one or more devices 500 and one or more components of device 500. As shown in FIG. 5, device 500 may include a bus 510, a processor 520, a memory 530, a storage component 540, an input component 550, an output component 560, and a communication component 570.

Bus 510 includes a component that enables wired or wireless communication among the components of device 500. Processor 520 includes a central processing unit, a graphics processing unit, a microprocessor, a controller, a microcontroller, a digital signal processor, a field-programmable gate array, an application-specific integrated circuit, or another type of processing component. Processor 520 is implemented in hardware, firmware, or a combination of hardware and software. In some implementations, processor 520 includes one or more processors capable of being programmed to perform a function. Memory 530 includes a random access memory, a read only memory, or another type of memory (e.g., a flash memory, a magnetic memory, or an optical memory).

Storage component 540 stores information or software related to the operation of device 500. For example, storage component 540 may include a hard disk drive, a magnetic disk drive, an optical disk drive, a solid state disk drive, a compact disc, a digital versatile disc, or another type of non-transitory computer-readable medium. Input component 550 enables device 500 to receive input, such as user input or sensed inputs. For example, input component 550 may include a touch screen, a keyboard, a keypad, a mouse, a button, a microphone, a switch, a sensor, a global positioning system component, an accelerometer, a gyroscope, or an actuator. Output component 560 enables device 500 to provide output, such as via a display, a speaker, or one or more light-emitting diodes. Communication component 570 enables device 500 to communicate with other devices, such as via a wired connection or a wireless connection. For example, communication component 570 may include a receiver, a transmitter, a transceiver, a modem, a network interface card, or an antenna.

Device 500 may perform one or more processes described herein. For example, a non-transitory computer-readable medium (e.g., memory 530 or storage component 540) may store a set of instructions (e.g., one or more instructions, code, software code, or program code) for execution by processor 520. Processor 520 may execute the set of instructions to perform one or more processes described herein. In some implementations, execution of the set of instructions, by one or more processors 520, causes the one or more processors 520 or the device 500 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 5 are provided as an example. Device 500 may include additional components, fewer components, different components, or differently arranged components than those shown in FIG. 5. Additionally, or alternatively, a set of components (e.g., one or more components) of device 500 may perform one or more functions described as being performed by another set of components of device 500.

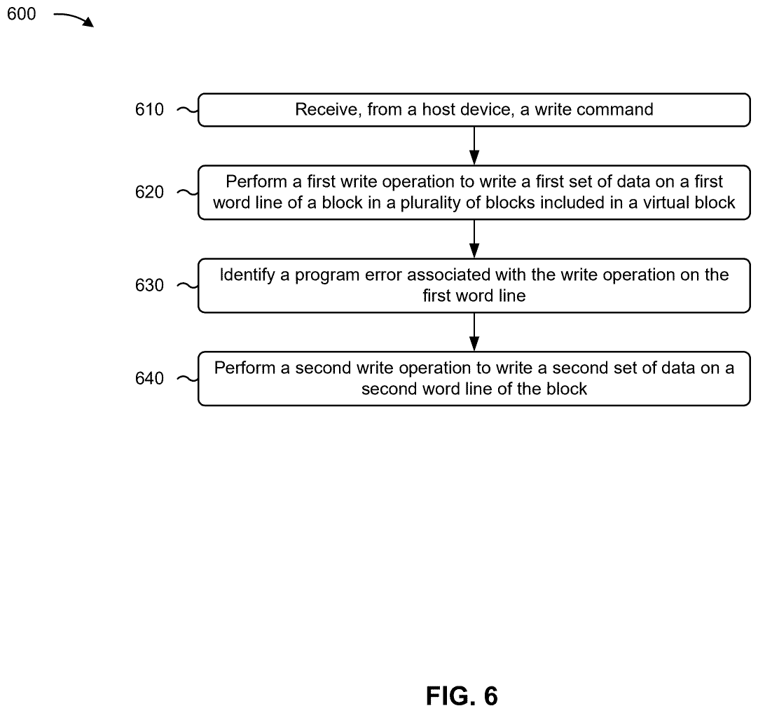

FIG. 6 is a flowchart of an example process 600 associated with program error handling at a storage device described herein. In some implementations, one or more process blocks of FIG. 6 may be performed by a storage device. In some implementations, one or more process blocks of FIG. 6 may be performed by another device or a group of devices separate from or including the storage device, such as a controller. Additionally, or alternatively, one or more process blocks of FIG. 6 may be performed by one or more components of device 500, such as processor 520, memory 530, storage component 540, input component 550, output component 560, or communication component 570. Additionally, or alternatively, one or more process blocks of FIG. 6 may be performed by one or more components of FIG. 4, such as controller 405, SOC 410, processors 415, or storage media interface 435.

As shown in FIG. 6, process 600 may include receiving, from a host device, a write command (block 610). For example, the storage device may receive, from a host device, a write command, as described above.

As further shown in FIG. 6, process 600 may include performing a first write operation to write a first set of data on a first word line of a block in a plurality of blocks included in a virtual block (block 620). For example, the storage device may perform a first write operation to write a first set of data on a first word line of a block in a plurality of blocks included in a virtual block, as described above.

As further shown in FIG. 6, process 600 may include identifying a program error associated with the write operation on the first word line (block 630). For example, the storage device may identify a program error associated with the write operation on the first word line, as described above.

As further shown in FIG. 6, process 600 may include performing a second write operation to write a second set of data on a second word line of the block (block 640). For example, the storage device may perform a second write operation to write a second set of data on a second word line of the block, as described above.

Process 600 may include additional implementations, such as any single implementation or any combination of implementations described below and/or in connection with one or more other processes described elsewhere herein.

In a first implementation, the second word line is separated from the first word line by a quantity of word lines.

In a second implementation, alone or in combination with the first implementation, process 600 includes writing dummy data to one or more word lines between the first word line and the second word line.

In a third implementation, alone or in combination with one or more of the first and second implementations, performing the second write operation on the second word line of the block is based at least in part on detecting no program error associated with performing dummy data write on at least a last word line of the one or more word lines.

In a fourth implementation, alone or in combination with one or more of the first through third implementations, the block in the plurality of blocks is a first block, the method comprising performing the write operation on a word line of a second block in the plurality of blocks, wherein the word line of the second block is associated with a word line index that corresponds to the first word line.

In a fifth implementation, alone or in combination with one or more of the first through fourth implementations, the block in the plurality of blocks included the virtual block is a first block in a first plurality of blocks included a first virtual block, the method comprising scanning a previous word line within the block based at least in part on identifying the program error, identifying a scan read error on the previous word line, and writing data associated with the previous word line on a second virtual block based at least in part on the scan read error.

In a sixth implementation, alone or in combination with one or more of the first through fifth implementations, a second plurality of blocks is included in the second virtual block, wherein writing the data associated with the previous word line on the second virtual block comprises writing the data associated with the previous word line on a third word line of a third block in the second plurality of blocks.

In a seventh implementation, alone or in combination with one or more of the first through sixth implementations, process 600 includes moving, to the second virtual block and based at least in part on identifying the additional scan read error on the previous word line, data written to the first virtual block at multiple blocks.

In an eighth implementation, alone or in combination with one or more of the first through seventh implementations, process 600 includes scanning a previous word line within the block based at least in part on identifying the program error, identifying no program error on the previous word line, and maintaining data on the previous word line based at least in part on identifying no program error on the previous word line.

In a ninth implementation, alone or in combination with one or more of the first through eighth implementations, the block in the plurality of blocks included the virtual block is a first block in a first plurality of blocks included a first virtual block, the method comprising identifying, after performing the write operation on the second word line of the virtual block, a quantity of program errors on the virtual block, and moving, to a second virtual block, data written to the virtual block at multiple blocks.

In a tenth implementation, alone or in combination with one or more of the first through ninth implementations, the second set of data is the same as the first set of data, or wherein the second set of data is different from the first set of data.

Although FIG. 6 shows example blocks of process 600, in some implementations, process 600 may include additional blocks, fewer blocks, different blocks, or differently arranged blocks than those depicted in FIG. 6. Additionally, or alternatively, two or more of the blocks of process 600 may be performed in parallel.

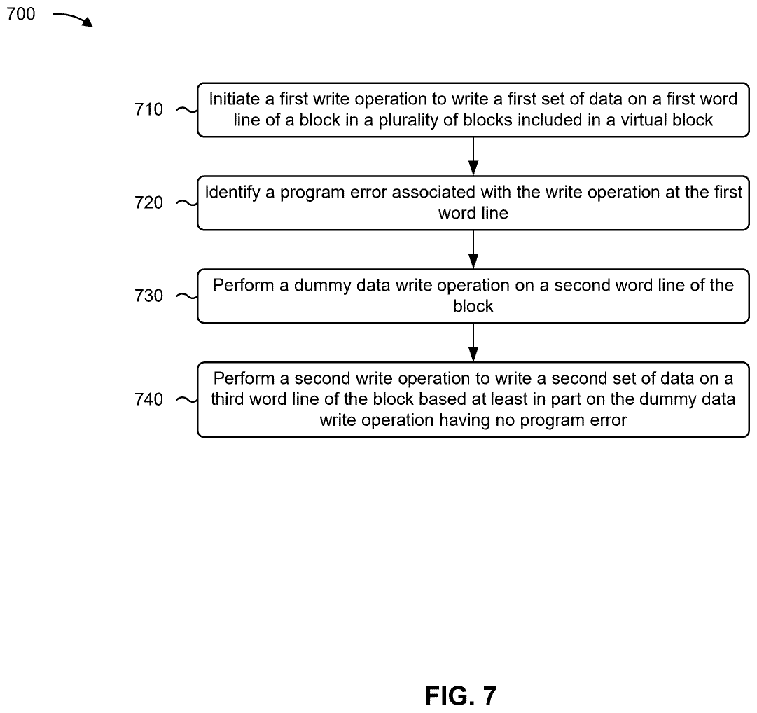

FIG. 7 is a flowchart of an example process 700 associated with program error handling at a storage device described herein. In some implementations, one or more process blocks of FIG. 7 may be performed by a storage device. In some implementations, one or more process blocks of FIG. 7 may be performed by another device or a group of devices separate from or including the storage device, such as a controller. Additionally, or alternatively, one or more process blocks of FIG. 7 may be performed by one or more components of device 500, such as processor 520, memory 530, storage component 540, input component 550, output component 560, or communication component 570. Additionally, or alternatively, one or more process blocks of FIG. 7 may be performed by one or more components of FIG. 4, such as controller 405, SOC 410, processors 415, or storage media interface 435.

As shown in FIG. 7, process 700 may include initiating a first write operation to write a first set of data on a first word line of a block in a plurality of blocks included in a virtual block (block 710). For example, the storage device may initiate a first write operation to write a first set of data on a first word line of a block in a plurality of blocks included in a virtual block, as described above.

As further shown in FIG. 7, process 700 may include identifying a program error associated with the write operation at the first word line (block 720). For example, the storage device may identify a program error associated with the write operation at the first word line, as described above.

As further shown in FIG. 7, process 700 may include performing a dummy data write operation on a second word line of the block (block 730). For example, the storage device may perform a dummy data write operation on a second word line of the block, as described above.

As further shown in FIG. 7, process 700 may include performing a second write operation to write a second set of data on a third word line of the block based at least in part on the dummy data write operation having no program error (block 740). For example, the storage device may perform a second write operation to write a second set of data on a third word line of the block based at least in part on the dummy data write operation having no program error, as described above.

Process 700 may include additional implementations, such as any single implementation or any combination of implementations described below and/or in connection with one or more other processes described elsewhere herein.

In a first implementation, the second word line is a next sequential word line of block, or wherein the second word line is separated from the first word line by a quantity of word lines.

In a second implementation, alone or in combination with the first implementation, process 700 includes performing a scan read of a previous word line within the block based at least in part on identifying the program error.

In a third implementation, alone or in combination with one or more the first and second implementations, the block in the plurality of blocks included the virtual block is a first block in a first plurality of blocks included a first virtual block, and process 700 further comprises, based at least in part on identifying an additional program error on the previous word line, moving, to a second virtual block, data written to the virtual block at multiple blocks.

In a fourth implementation, alone or in combination with one or more of the first through third implementations, process 700 includes scanning a previous word line within the block based at least in part on identification of the program error, identifying no program error on the previous word line, and maintaining data on the previous word line.

Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel.

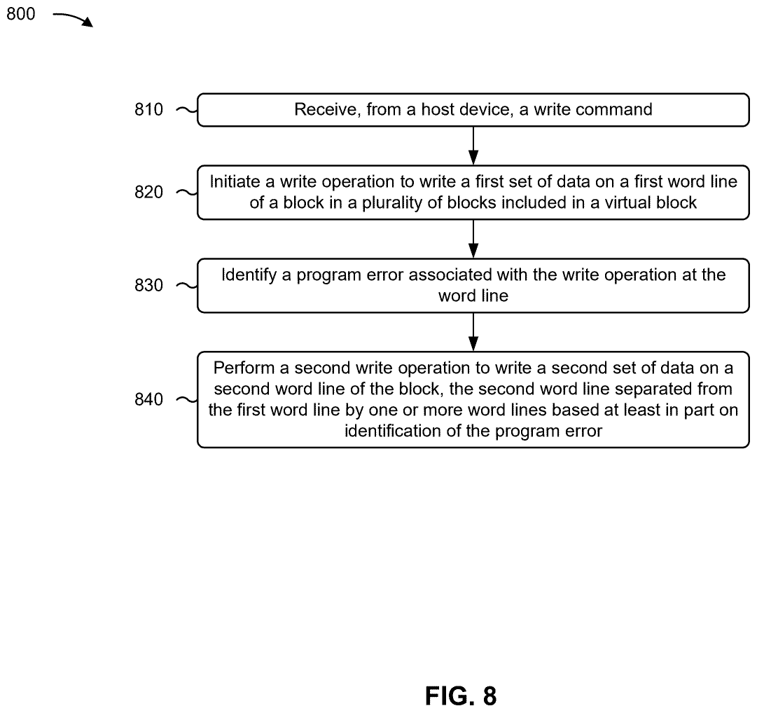

FIG. 8 is a flowchart of an example process 800 associated with program error handling at a storage device described herein. In some implementations, one or more process blocks of FIG. 8 may be performed by a storage device. In some implementations, one or more process blocks of FIG. 8 may be performed by another device or a group of devices separate from or including the storage device, such as a controller. Additionally, or alternatively, one or more process blocks of FIG. 8 may be performed by one or more components of device 500, such as processor 520, memory 530, storage component 540, input component 550, output component 560, or communication component 570. Additionally, or alternatively, one or more process blocks of FIG. 8 may be performed by one or more components of FIG. 4, such as controller 405, SOC 410, processors 415, or storage media interface 435.

As shown in FIG. 8, process 800 may include receiving, from a host device, a write command (block 810). For example, the storage device may receive, from a host device, a write command, as described above.

As further shown in FIG. 8, process 800 may include initiating a write operation to write a first set of data on a first word line of a block in a plurality of blocks included in a virtual block (block 820). For example, the storage device may initiate a write operation to write a first set of data on a first word line of a block in a plurality of blocks included in a virtual block, as described above.

As further shown in FIG. 8, process 800 may include identifying a program error associated with the write operation at the word line (block 830). For example, the storage device may identify a program error associated with the write operation at the word line, as described above.

As further shown in FIG. 8, process 800 may include performing a second write operation to write a second set of data on a second word line of the block, the second word line separated from the first word line by one or more word lines based at least in part on identification of the program error (block 840). For example, the storage device may perform a second write operation to write a second set of data on a second word line of the block, the second word line separated from the first word line by one or more word lines based at least in part on identification of the program error, as described above.

Process 800 may include additional implementations, such as any single implementation or any combination of implementations described below and/or in connection with one or more other processes described elsewhere herein.

In a first implementation, process 800 includes programming instructions to write dummy data to the word lines between the first word line and the second word line.

In a second implementation, alone or in combination with the first implementation, performing the second write operation comprises writing the second set of data on the second word line of the block based at least in part on detecting no program error on at least a last word line of the word lines between the first word line and the second word line.

In a third implementation, alone or in combination with one or more of the first and second implementations, process 800 includes scanning a previous word line within the block based at least in part on identification of the program error, and maintaining data on the previous word line based at least in part on identification of no scan read error on the previous word line.

In a fourth implementation, alone or in combination with one or more of the first through third implementations, the block in the plurality of blocks included the virtual block is a first block in a first plurality of blocks included a first virtual block, and process 800 includes scanning a previous word line within the block based at least in part on identifying the program error, and writing data associated with the previous word line on a second virtual block based at least in part on detection of a scan read error on the previous word line.

In a fifth implementation, alone or in combination with one or more of the first through fourth implementations, the block in the plurality of blocks included the virtual block is a first block in a first plurality of blocks included a first virtual block, and process 800 includes identifying, after performing the write operation on the second word line of the virtual block, a quantity of program errors on the virtual block, and moving, to a second virtual block, data written to the virtual block at multiple blocks.

Although FIG. 8 shows example blocks of process 800, in some implementations, process 800 may include additional blocks, fewer blocks, different blocks, or differently arranged blocks than those depicted in FIG. 8. Additionally, or alternatively, two or more of the blocks of process 800 may be performed in parallel.

As used herein, the term “component” is intended to be broadly construed as hardware, firmware, or a combination of hardware and software. It will be apparent that systems or methods described herein may be implemented in different forms of hardware, firmware, or a combination of hardware and software. The actual control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with other claims in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein is to be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method performed by a storage device, the method comprising:
receiving, from a host device, a write command;
performing a first write operation to write a first set of data on a first word line of a block in a plurality of blocks included in a virtual block;
identifying a program error associated with the write operation on the first word line; and
performing a second write operation to write a second set of data on a second word line of the block.

2. The method of claim 1, wherein the second word line is separated from the first word line by a quantity of word lines.

3. The method of claim 1, comprising:
writing dummy data to one or more word lines between the first word line and the second word line.

4. The method of claim 3, wherein performing the second write operation on the second word line of the block is based at least in part on detecting no program error associated with performing dummy data write on at least a last word line of the one or more word lines.

5. The method of claim 1, wherein the block in the plurality of blocks is a first block, the method comprising performing the write operation on a word line of a second block in the plurality of blocks,
wherein the word line of the second block is associated with a word line index that corresponds to the first word line.

6. The method of claim 1, wherein the block in the plurality of blocks included the virtual block is a first block in a first plurality of blocks included a first virtual block, the method comprising:
scanning a previous word line within the block based at least in part on identifying the program error;
identifying a scan read error on the previous word line; and
writing data associated with the previous word line on a second virtual block based at least in part on the scan read error.

7. The method of claim 6, wherein a second plurality of blocks is included in the second virtual block, wherein writing the data associated with the previous word line on the second virtual block comprises:
writing the data associated with the previous word line on a third word line of a third block in the second plurality of blocks.

8. The method of claim 6, comprising:
moving, to the second virtual block and based at least in part on identifying the additional scan read error on the previous word line, data written to the first virtual block at multiple blocks.

9. The method of claim 1, comprising:
scanning a previous word line within the block based at least in part on identifying the program error;
identifying no program error on the previous word line; and
maintaining data on the previous word line based at least in part on identifying no program error on the previous word line.

10. The method of claim 1, wherein the block in the plurality of blocks included the virtual block is a first block in a first plurality of blocks included a first virtual block, the method comprising:
identifying, after performing the write operation on the second word line of the virtual block, a quantity of program errors on the virtual block; and
moving, to a second virtual block, data written to the virtual block at multiple blocks.

11. The method of claim 1, wherein the second set of data is the same as the first set of data, or
wherein the second set of data is different from the first set of data.

12. A system comprising:
a controller, of a non-volatile memory device, to:
initiate a first write operation to write a first set of data on a first word line of a block in a plurality of blocks included in a virtual block;
identify a program error associated with the write operation at the first word line;
perform a dummy data write operation on a second word line of the block; and
perform a second write operation to write a second set of data on a third word line of the block based at least in part on the dummy data write operation having no program error.

13. The system of claim 12, wherein the second word line is a next sequential word line of block, or
wherein the second word line is separated from the first word line by a quantity of word lines.

14. The system of claim 12 wherein the controller is to:
perform a scan read of a previous word line within the block based at least in part on identifying the program error.

15. The system of claim 14, wherein the block in the plurality of blocks included the virtual block is a first block in a first plurality of blocks included a first virtual block, and
wherein the controller is to, based at least in part on identifying an additional program error on the previous word line, move, to a second virtual block, data written to the virtual block at multiple blocks.

16. The system of claim 12, wherein the controller is to:
scan a previous word line within the block based at least in part on identification of the program error;
identify no program error on the previous word line; and
maintain data on the previous word line.

17. A computer program product comprising:
one or more computer readable storage media, and program instructions collectively stored on the one or more computer readable storage media, the program instructions comprising:
program instructions to receive, from a host device, a write command;
program instructions to initiate a write operation to write a first set of data on a first word line of a block in a plurality of blocks included in a virtual block;
program instructions to identify a program error associated with the write operation at the word line; and
program instructions to perform a second write operation to write a second set of data on a second word line of the block, the second word line separated from the first word line by one or more word lines based at least in part on identification of the program error.

18. The computer program product of claim 17, wherein the program instructions comprise:
program instructions to write dummy data to the word lines between the first word line and the second word line.

19. The computer program product of claim 18, wherein, to perform the second write operation, the program instructions comprise:
program instructions to write the second set of data on the second word line of the block based at least in part on detecting no program error on at least a last word line of the word lines between the first word line and the second word line.

20. The computer program product of claim 17, wherein the program instructions comprise:
program instructions to scan a previous word line within the block based at least in part on identification of the program error; and
program instructions to maintain data on the previous word line based at least in part on identification of no scan read error on the previous word line.

21. The computer program product of claim 17, wherein the block in the plurality of blocks included the virtual block is a first block in a first plurality of blocks included a first virtual block, and wherein the program instructions comprise:
program instructions to scan a previous word line within the block based at least in part on identifying the program error; and
program instructions to write data associated with the previous word line on a second virtual block based at least in part on detection of a scan read error on the previous word line.

22. The computer program product of claim 17, wherein the block in the plurality of blocks included the virtual block is a first block in a first plurality of blocks included a first virtual block, and wherein the program instructions comprise:
program instructions to identify, after performing the write operation on the second word line of the virtual block, a quantity of program errors on the virtual block; and
program instructions to move, to a second virtual block, data written to the virtual block at multiple blocks.
